(19) United States
(12) Patent Application Publication
(10) Pub. No.: US 2007/0251566 A1
(43) Pub. Date: Nov. 1, 2007

(54) Light Source Integrated Photovoltaic Module and Power-Generating Light-Emitting Unit Using Same

(75) Inventors: Takashi Ouchida, Kitakatsuragi-gun (JP); Hitoshi Sannomiya, Osaka-shi (JP); Kazuhiko Ashihara, Kyoto-shi (JP)

Correspondence Address: NIXON & VANDERHYE, PC, 901 NORTH GLEBE ROAD, 11TH FLOOR, ARLINGTON, VA, 22203, US

(73) Assignee: SHARP KABUSHIKI KAISHA, Osaka (JP)

(21) Appl. No.: 11/578,791

(22) PCT Filed: Apr. 11, 2005
(86) PCT No.: PCT/JP05/07029

§ 371 Date: Oct. 18, 2006

(30) Foreign Application Priority Data
Apr. 19, 2004 (JP) 2004-122991

(51) Int. Cl. H01L 31/042

(52) U.S. Cl. 136/244

(57) ABSTRACT

The present invention provides a light source integrated photovoltaic module. The light source integrated photovoltaic module comprises: a light-transmitting photovoltaic cell having a front surface and a back surface; and a light source provided on the back surface side of the photovoltaic cell. The photovoltaic cell generates electric power by utilizing incident light from the front surface side, the light emits light by utilizing the electric power generated by the photovoltaic cell. The light emitted from the light source is transmitted through the photovoltaic cell and outputted to the front surface side of the photovoltaic cell.

### TECHNICAL FIELD

The present invention relates to a light source integrated photovoltaic module and a power-generating light-emitting unit using the same, and particularly to a photovoltaic module having both function of a power generating function and a light emitting function and a power-generating light-emitting unit using the same.

### BACKGROUND ART

In a general photovoltaic panel, a panel surface has a single color. For example, a color of a front surface of a photovoltaic module constituting the panel is limited to black or blue-purple in a case of a crystalline cell and brown in a case of an amorphous cell. As a result, expression of the panel becomes very bleak and harsh.

Therefore, there has been proposed a photovoltaic panel in which a front surface or a back surface of a photovoltaic module is colored with a desired color so that a desired pattern such as characters and graphics is displayed by combination of the photovoltaic modules having different colors. In detail, for example, the following photovoltaic panels are generally known.

A photovoltaic panel in which a desired color is given to a front surface of a photovoltaic module by adjusting a thickness, the number of laminated films, and a refractive index of an antireflective film, and plural photovoltaic modules having the different colors are combined to display characters and graphics (see, for example, Patent Document 1).

A photovoltaic panel in which a translucent sealing material for a back side of a light-transmitting photovoltaic module is colored with a desired color and plural photovoltaic modules having the different colors are combined to display characters, graphics and patterns (see, for example, Patent Document 2).

On the other hand, there is also proposed a photovoltaic panel in which a photovoltaic cell and a light source are integrated to use electric power stored during the daytime for lighting in the nighttime. For example, the following photovoltaic panels are generally known.

A light emitting apparatus which includes a translucent substrate, a translucent light-emitting layer laminated on the translucent substrate, a photovoltaic cell laminated on the translucent light-emitting layer, a battery for storing electric power generated by the photovoltaic cell, and a control unit for controlling both charge from the photovoltaic cell to the battery and power supply from the battery to the translucent light-emitting layer, wherein the photovoltaic cell generates the electric power by receiving incident light through the translucent substrate and the translucent light-emitting layer, and light emitted from the translucent light-emitting layer is outputted to the outside through the translucent substrate (see, for example, Patent Document 3).

A light emitting apparatus which includes a light emitting panel for performing plane light emission, a frame-shape photovoltaic cell for surrounding the light emitting panel, a battery for storing the electric power generated by the photovoltaic cell, a control unit for controlling both charge from the photovoltaic cell to the battery and power supply from the battery to the light emitting panel, and a casing for accommodating these components (see, for example, Patent Document 4).

A light emitting apparatus in which photovoltaic cell and a light emitting device are arranged on one surface of a substrate, an electronic circuit for driving the light emitting device to emit light is arranged on the other surface, and the photovoltaic cell, the light emitting device, and the electronic circuit are electrically connected to one another through a through-hole formed in the substrate (see, for example, Patent Document 5).

Patent Document 1: Japanese Unexamined Patent Publication No. Hei8 (1996)-107230

Patent Document 2: Japanese Unexamined Patent Publication No. 2001-237449

Patent Document 3: Japanese Unexamined Patent Publication No. Sho59 (1984)-217991

Patent Document 4: Japanese Unexamined Patent Publication No. Sho60 (1985)-78477

Patent Document 5: Japanese Unexamined Patent Publication No. 2001-351418

### DISCLOSURE OF THE INVENTION

### Problems to be Solved by the Invention

In a case of the photovoltaic panel in which the desired color is given to the front surface or back surface of the photovoltaic module and the desired pattern is displayed by combining the photovoltaic modules having the different colors, a display effect of the pattern can be obtained only during the daytime. Furthermore, the pattern which can be displayed by the photovoltaic panel is limited to one kind.

On the other hand, in the light emitting apparatus in which the photovoltaic cell and the light source are integrated, in a case where the translucent light-emitting layer is arranged on a light incident surface of the photovoltaic cell, power generation efficiency is decreased in the photovoltaic cell, because loss of the incident light is generated due to the translucent light-emitting layer. In the light emitting apparatus in which the photovoltaic cell and the light source such as the light emitting panel and the light emitting device are arranged so as not to overlap with each other on a same plane, although the decrease in power generation efficiency is not generated, the light emission cannot be taken out from a region where the photovoltaic cell is arranged. Therefore, the overall plane light emission cannot be performed, there are still left problems from the standpoints of visibility and design.

In view of the foregoing, the present invention provides a light source integrated photovoltaic module which can achieve the overall plane light emission while the decrease in power generation efficiency is suppressed at the minimum, and a power-generating light-emitting system using the same.

### MEANS FOR SOLVING THE PROBLEMS

According to the present invention, there is provided a light source integrated photovoltaic module which includes a light-transmitting photovoltaic cell having a front surface and a back surface; and a light source provided on the back surface side of the photovoltaic cell, wherein the photovoltaic cell generates electric power by utilizing incident light from the front surface side, the light source emits light by utilizing the electric power generated by the photovoltaic cell, and the light emitted from the light source is transmitted through the photovoltaic cell and outputted to the front surface side of the photovoltaic cell.

### EFFECT OF THE INVENTION

According to the present invention, since the light source is arranged on the back surface side of the light-transmitting photovoltaic cell, loss of the incident light due to the light source is eliminated, and the light emitted from the light source is transmitted through the photovoltaic cell and outputted to the front surface side of the photovoltaic cell. Therefore, the overall plane light emission can be achieved. As a result, the light source integrated photovoltaic module having excellent visibility and design can be provided.

### BRIEF DESCRIPTION OF THE DRAWINGS

FIG. 1 is a front view schematically illustrating the construction of a light source integrated photovoltaic module according to an embodiment;

FIG. 2 is a sectional view taken along line A-A schematically illustrating the construction of the light source integrated photovoltaic module shown in FIG. 1;

FIG. 3 is an explanatory view illustrating the action of the light source integrated photovoltaic module shown in FIG. 2 during the power generation;

FIG. 4 is an explanatory view illustrating the action of the light source integrated photovoltaic module shown in FIG. 2 during the light emission;

FIG. 5 is a plan view of an integrated thin-film cell constituting the light source integrated photovoltaic module;

FIG. 6 is a sectional view taken along line B-B of the essential portion of the integrated thin film cell shown in FIG. 5;

FIG. 7 is a sectional view taken along line C-C of the essential portion of the integrated thin-film cell shown in FIG. 5;

FIG. 8 is a perspective view of an LED lighting device;

FIG. 9 is a plan view of an LED substrate constituting the LED lighting device;

FIG. 10 is a diagram for explaining a production process for the integrated thin-film cell;

FIG. 11 is a diagram for explaining a production process for the integrated thin-film cell;

FIG. 12 is a diagram for explaining a production process for the photovoltaic module;

FIG. 13 is an explanatory view illustrating the assembling process for the light source integrated photovoltaic module;

FIG. 14 is a front view of a power-generating light-emitting system according to an embodiment; and

FIG. 15 is a front view of a modification of the power-generating light-emitting system shown in FIG. 14.

### DESCRIPTION OF THE REFERENCE NUMERALS

10 photovoltaic module
11 front-surface cover glass
12 EVA sheet
13 transparent-PET-coated bus bar
14 black PET film
15 back-surface cover glass
16 terminal box
17 cable line
18 module frame
20 integrated thin-film cell
21 glass substrate
22 transparent conductive film
23 separation line
24 first photoelectric conversion layer
25 second photoelectric conversion layer
26 photoelectric conversion layer
27 contact line
28 back-surface electrode layer
29 separation line
30 opening
31 collector electrode
32 trimming portion
40 reflecting plate
41 partition plate
50 LED lighting device
51 LED substrate
52 LED element
53 casing
60 light source integrated photovoltaic module
70 power-generating light-emitting system
71 logo
100 sunlight
200 LED light

### BEST MODE FOR CARRYING OUT THE INVENTION

A light source integrated photovoltaic module according to the present invention includes a light-transmitting photovoltaic cell having a front surface and a back surface and a light source provided on the back surface side of the photovoltaic cell, wherein the photovoltaic cell generates the electric power by utilizing the incident light from the front surface side, the light source emits the light by utilizing the electric power generated by the photovoltaic cell, and the light emitted from the light source is transmitted through the photovoltaic cell and outputted to the front surface side of the photovoltaic cell. In the light source integrated photovoltaic module of the present invention, the photovoltaic cell is not limited as long as it is light-transmitting type, and either crystalline photovoltaic cell or a thin-film cell can be used. As to a configuration of the photovoltaic cell, either a single cell or a photovoltaic module in which plural cells are electrically connected can be used. In the present invention, the term of light source can be replaced by a light emitting device, and the light source shall include all devices which emit the light with the electric power. Specifically, preferably the light source has low electric power consumption and high brightness. Examples of the light source include an LED element, an organic EL device, an inorganic EL device, a cold cathode fluorescent lamp, and a hot cathode fluorescent lamp.

The light source integrated photovoltaic module of the present invention may further include a reflecting plate, which covers the back surface side of the photovoltaic cell and accommodates the light source therein, and the photovoltaic cell may have a substantially square shape, and the light source may be arranged along at least one edge of the photovoltaic cell, and the light emitted from the light source may be reflected by the reflecting plate and transmitted from the back surface side to the front surface side of the photovoltaic cell. According to the above configuration, overall plane light emission can efficiently be performed by action of the reflecting plate while the electric power consumption is suppressed in the light source. That is, in order to obtain the overall plane light emission with the uniform brightness, it is needed that the back surface side of the photovoltaic cell is uniformly irradiated. If the light source is arranged such that the whole of the back surface of the photovoltaic cell is covered with the light source, the number of light sources becomes extremely large, or the large light source is required, and the electric power consumption is increased accordingly. However, as described above, the light source is arranged along the edge of the photovoltaic cell, and the light emitted from the light source is reflected by the reflecting plate to uniformly irradiate the back surface of the photovoltaic cell with the light. Therefore, the back surface of the photovoltaic cell can uniformly be irradiated with the light emitted from the small number of light sources or the small light source, and the overall plane light emission can be obtained with the uniform brightness while the electric power consumption is suppressed.

In the above configuration having the reflecting plate, the light sources may be arranged on both edges of the photovoltaic cell, the reflecting plate may include a partition plate which partitions the reflecting region in each light source to independently output the light emitted by each light source from the photovoltaic cell. According to the above configuration, since the light emitted by each light source can independently be outputted from the photovoltaic cell, the expression as a display device of the light source integrated photovoltaic module becomes excellent, where the light sources arranged on both the edges of the photovoltaic cell emit the different colors respectively.

In the light source integrated photovoltaic module of the present invention, the photovoltaic cell may have a photoelectric conversion layer which performs photoelectric conversion, and an opening may be formed in a part of the photoelectric conversion layer to transmit the light emitted by the light source from the back surface side to the front surface side. According to the above configuration, the light-transmitting photovoltaic cell can be obtained by a simple structure in which the opening is formed in a part of the photoelectric conversion layer. In this case, since transmittance of the whole of photovoltaic cell is determined by a ratio of the opening to an area of the whole of photovoltaic cell, the transmittance of the whole of photovoltaic cell can be easily set. For example, the opening can be easily formed by laser processing. In order to obtain the overall plane light emission with the uniform brightness, it is preferable that the many openings be formed with a uniform distribution as much as possible.

In the configuration in which the opening is formed in the photoelectric conversion layer of the photovoltaic cell, the photovoltaic cell may have a tandem structure in which the photoelectric conversion layer made of amorphous and the photoelectric conversion layer silicon made of microcrystalline silicon are laminated. According to the above configuration, when compared with the single structure in which the photoelectric conversion layer is made of only amorphous silicon, conversion efficiency is improved about 1.5 times, and the color of the photovoltaic cell becomes close to black from brown. Therefore, the configuration has the excellent design as back color of the display device.

In the configuration in which the opening is formed in the photoelectric conversion layer of the photovoltaic cell, a reflecting surface which reflects the light emitted from the light source may be formed in the back surface of the photovoltaic cell. According to the above configuration, in the case where the reflecting plate is provided on the back surface side of the photovoltaic cell, the light emitted from the light source can be confined between the reflecting plate and the back surface of the photovoltaic cell until the light is transmitted through the opening and outputted from the front surface side, and use efficiency of the light emitted from the light source can be enhanced. As a result, the number of light sources can be decreased or the miniaturization of the light source can be achieved, and the decrease in electric power consumption can be achieved.

In the configuration in which the opening is formed in the photoelectric conversion layer of the photovoltaic cell, the opening may be formed such that an area ratio of the opening to an effective power generation region of the photovoltaic cell ranges from 5% to 30%. According to the above configuration, the light emitted from the light source can be efficiently transmitted to the front surface side of the photovoltaic cell while a balance is kept between the power generation of the photovoltaic cell and the electric power consumption of the light source. That is, where the ratio of the opening is smaller than 5%, the area which transmits the light emitted from the light source becomes excessively small, the light cannot efficiently be transmitted, and the overall plane light emission is hardly obtained with the uniform brightness. On the other hand, when the opening is larger than 30%, the area contributing to the photoelectric conversion becomes excessively small, the power generation efficiency is decreased, and the electric power necessary to the light emission cannot be supplied. In the present invention, the effective power generation region of the photovoltaic cell shall mean a region which receives the irradiation of the sunlight to contribute to the actual power generation, in the whole area of the photovoltaic cell. Generally, the effective power generation region shall mean a region where photoelectric conversion layer exists.

In the configuration in which the opening is formed in the photoelectric conversion layer of the photovoltaic cell, the photovoltaic cell may be a photovoltaic module in which a plurality of integrated cells are arranged so as to adjacent to each other, and a part of the adjacent integrated cells may be covered with film having transmittance similar to transmittance of the whole of the photovoltaic cell. That is, since a general integrated cell includes a non-transparent portion in which the photoelectric conversion layer exists and a transparent portion in which the photoelectric conversion layer does not exist, when the back surface side of the photovoltaic module including the integrated cell is irradiated, a region corresponding to the transparent portions of the adjacent cells becomes higher than other portions in the brightness, and the overall plane light emission is hardly obtained with the uniform brightness. However, when the above configuration is adopted, since a region of the pair of adjacent integrated cells, i.e., the transparent portions of the adjacent integrated cells are covered with the film having the transmittance similar to the transmittance of the whole of the photovoltaic cell, the transmittance of the whole of the photovoltaic cell can be uniformed, and the overall plane light emission is easily obtained with the uniform brightness.

In the light source integrated photovoltaic module of the present invention, the light source may comprise an LED lighting device. According to the above configuration, low electric power consumption, long lifetime, and low profile and weight reduction can be achieved by using LED as the light source. In addition to the above advantage, LED has an advantage that a blinking operation and the like are easily controlled, so that LED is suitable to the light source of the light source integrated photovoltaic module of the present invention.

The low electric power consumption means that sufficient light intensity is obtained only by the power generation with the photovoltaic cell, the long lifetime contributes to maintenance free of the light source integrated photovoltaic module, and the easy controllability has an advantage for constructing a colorful and advanced system as the display device.

In the configuration in which the light source is formed of the LED lighting device, the LED lighting device may include the plural LED elements which emit three RGB primary colors. According to the above configuration, not only the single color light can be emitted in the substantially whole visible light range, but also full-color display can be realized by combination of the three RGB primary colors.

In the configuration in which the LED lighting device includes the plural LED elements which emit the three RGB primary colors, the LED lighting device may include plural LED substrates on which the LED elements are mounted, and each LED substrate includes a control circuit which controls color development of the LED element. According to the above configuration, since the color development can independently be controlled in each LED substrate, the number of display patterns can be increased to perform the colorful and advanced display by increasing the number of LED substrates.

According to another aspect of the present invention, there is provided a power-generating light-emitting system which includes plural light source integrated photovoltaic modules arranged in a plane shape or a curved surface shape, wherein each of the light source integrated photovoltaic modules comprises the inventive light source integrated photovoltaic module described above. According to the above power-generating light-emitting system, characters, graphics, patterns, and the like can be displayed in the whole system during the nighttime by utilizing the electric power which is generated and stored in the daytime. Particularly, the power-generating light-emitting system of the present invention is useful as a large-area display system, and the power-generating light-emitting system can preferably function as advertising displays of stores or companies. Since the light source is provided on the back surface side of each photovoltaic cell, there is no possibility of decreasing the power generation efficiency of the photovoltaic cell. Additionally, the power-generating light-emitting system of the present invention is excellent in its appearance because the existence of the light source is invisible from the front surface side.

The power-generating light-emitting system of the invention may further include an object to be lit up on the front surface side of the light source integrated photovoltaic module. According to the above configuration, since the object to be lit up is provided in front of a part of the light source integrated photovoltaic modules, the power-generating light-emitting system can also function as the display device in the daytime in which the light source does not emit the light. Of course, since the object is lit up by the light emitted from the front surface side of the photovoltaic cell during the nighttime, the power-generating light-emitting system function further effectively as the display device. The characters and the desired graphics can be cited as an example of the object to be lit up. In this connection, the power generation efficiency of the light source integrated photovoltaic module in which the object to be lit up is arranged in front thereof is decreased by a shadow generated by the object, and the power generation efficiency of the whole of the power generating light-emitting system is also decreased. Therefore, from the standpoint of power generation efficiency of the whole of the power-generating light-emitting system, it is preferable that the light source integrated photovoltaic module is replaced with the dummy light source integrated photovoltaic module which does not have the power generation function, only in the portion where the power generation efficiency is possibly decreased by the object.

Then, the present invention will be described in detail based on an embodiment shown in the drawings.

### EMBODIMENT

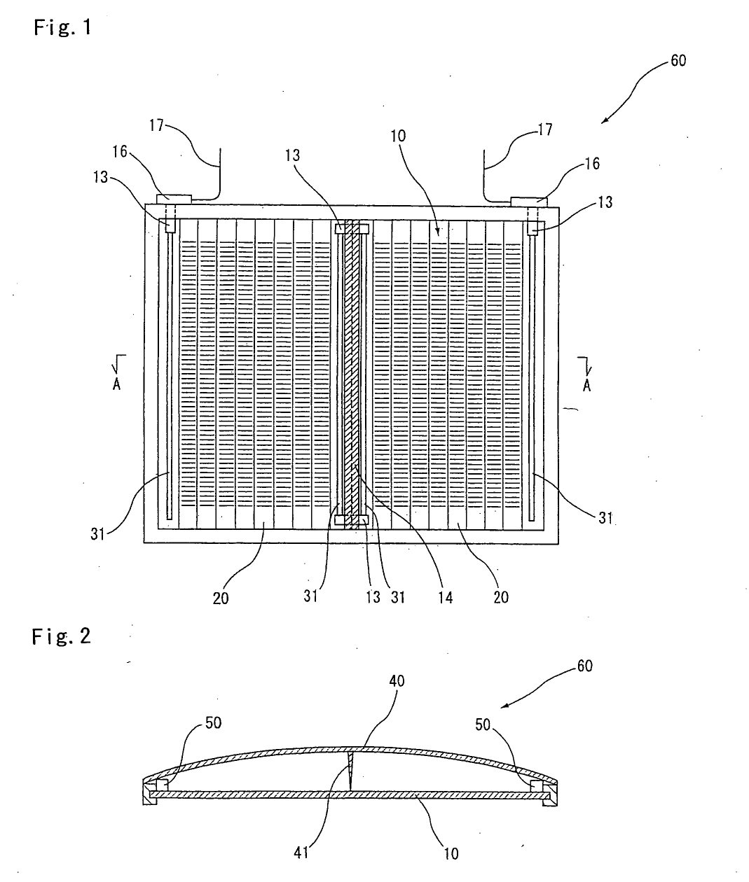

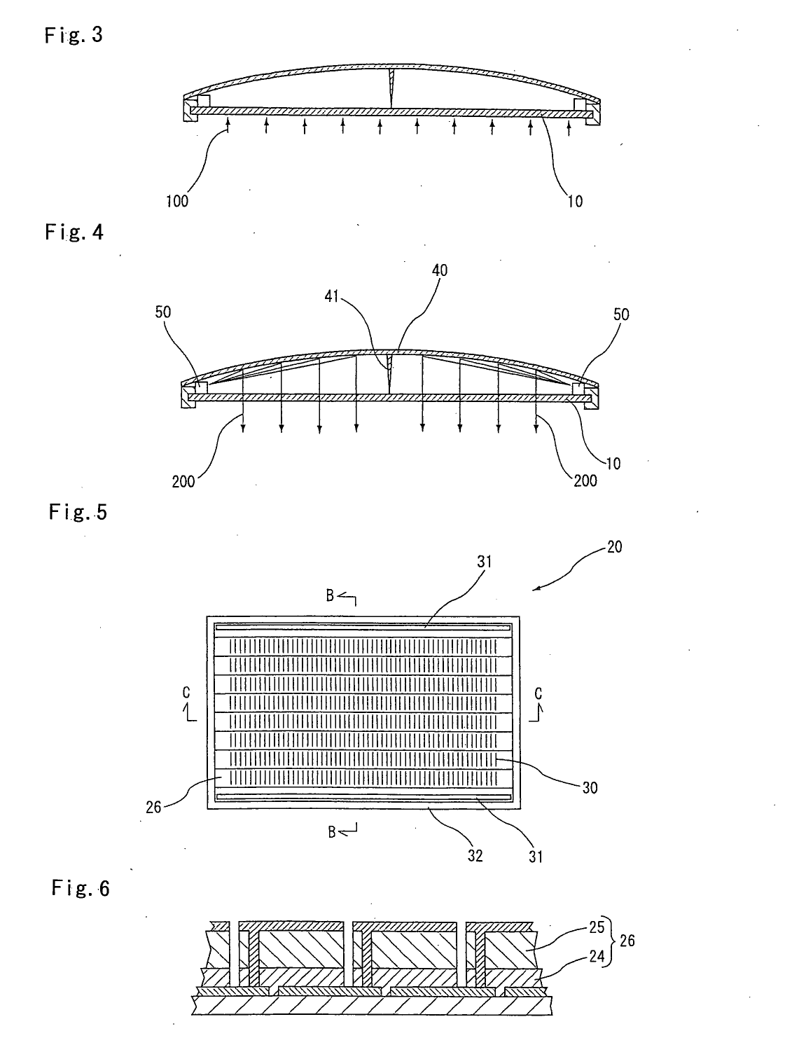

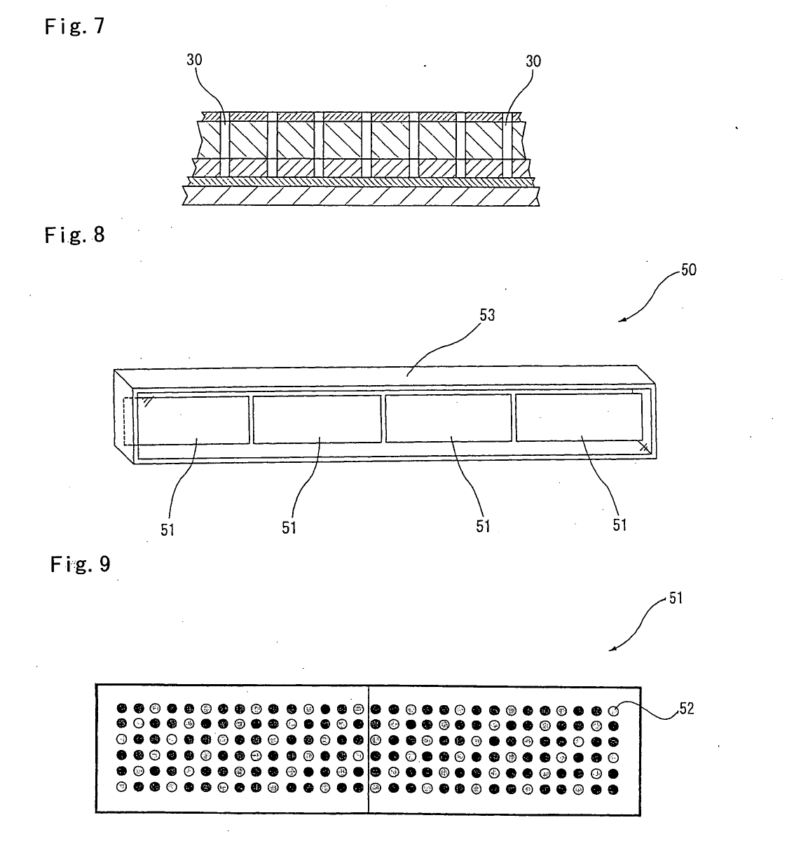

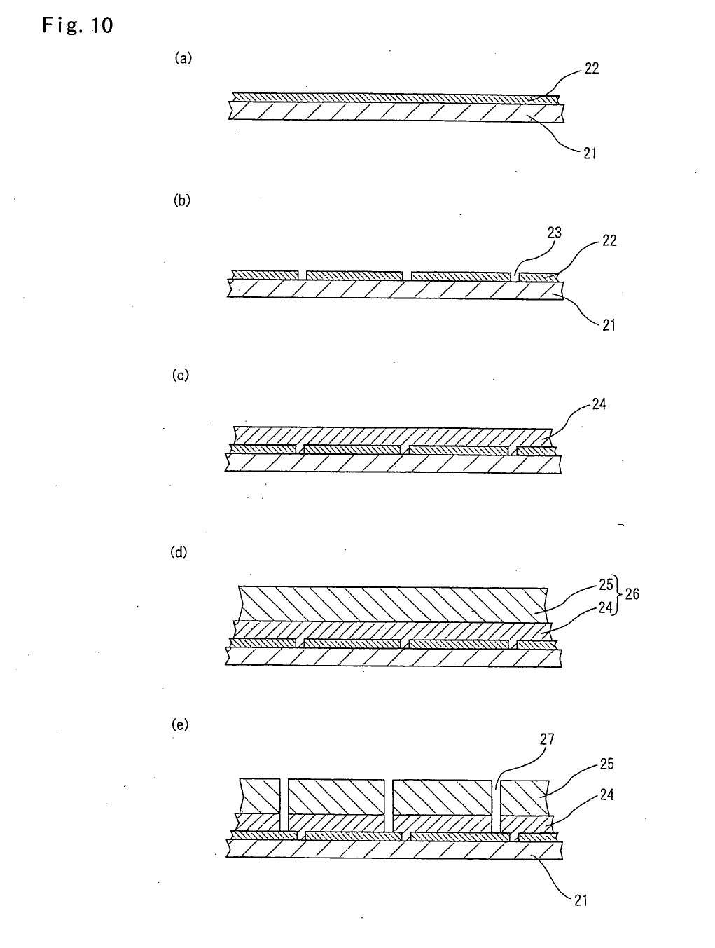

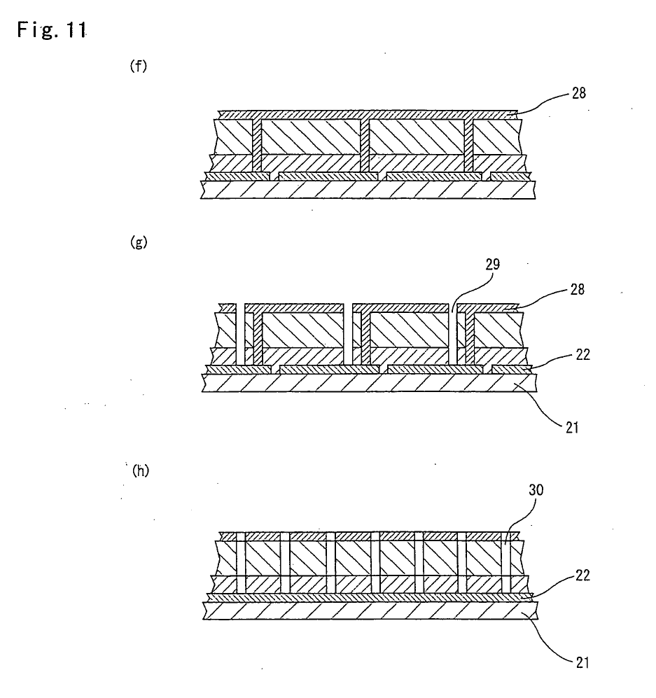

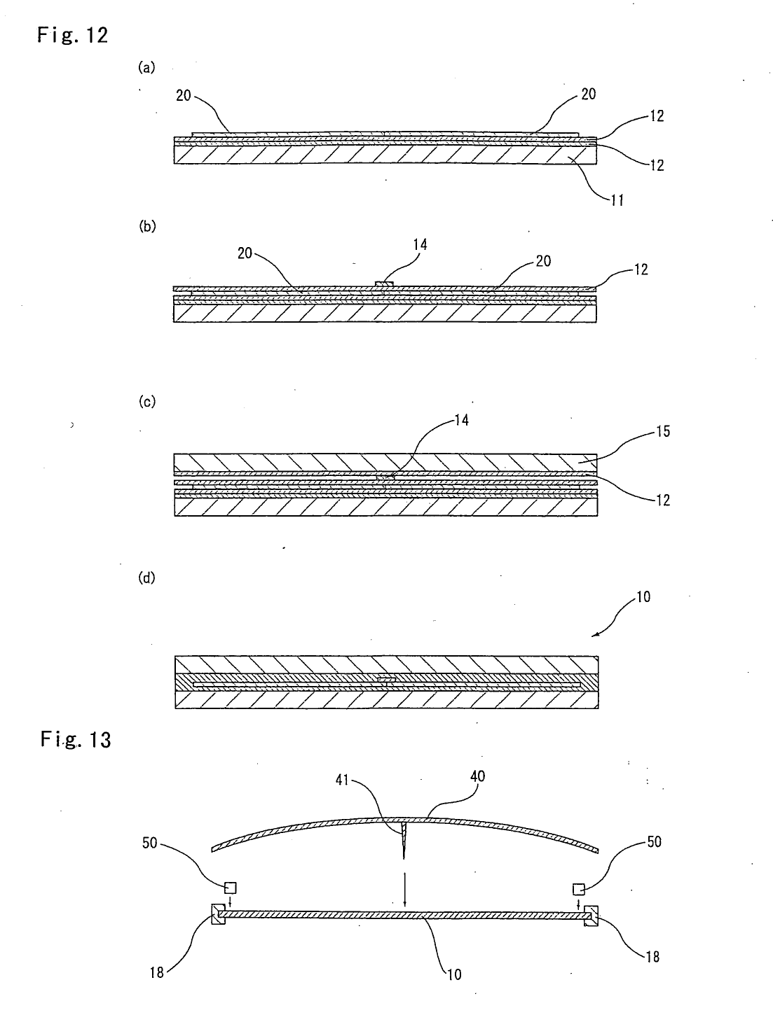

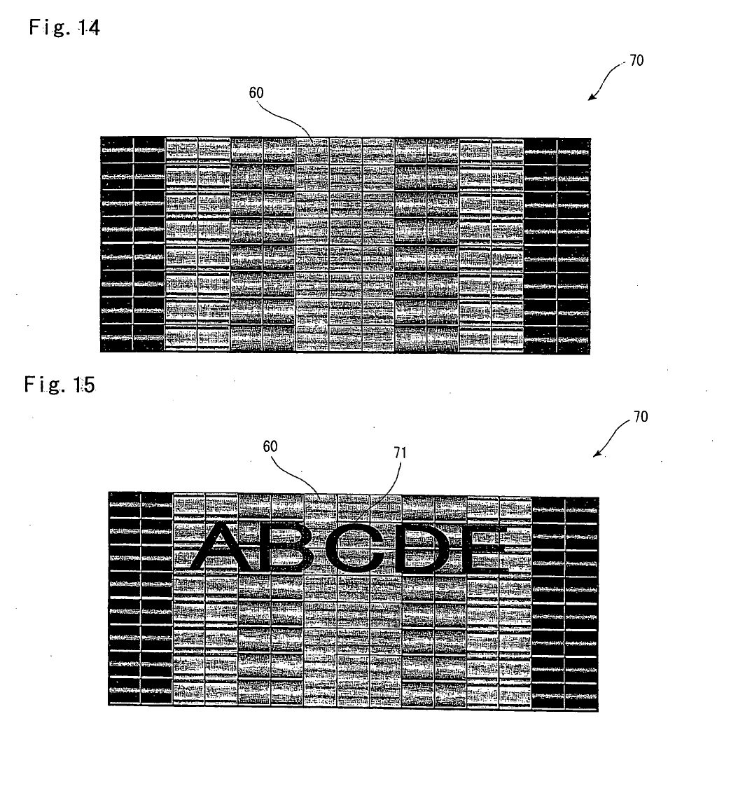

A light source integrated photovoltaic module according to an embodiment of the present invention and a power-generating light-emitting system using the same will be described with reference to FIGS. 1 to 15. FIG. 1 is a front view schematically illustrating the construction of the light source integrated photovoltaic module according to the embodiment. FIG. 2 is a sectional view taken along line A-A schematically illustrating the construction of the light source integrated photovoltaic module shown in FIG. 1. FIG. 3 is an explanatory view illustrating the action of the light source integrated photovoltaic module shown in FIG. 2 during the power generation. FIG. 4 is an explanatory view illustrating the action of the light source integrated photovoltaic module shown in FIG. 2 during the light emission. FIG. 5 is a plan view of an integrated thin-film cell constituting the light source integrated photovoltaic module. FIG. 6 is a sectional view taken along line B-B of the essential portion of the integrated thin film cell shown in FIG. 5. FIG. 7 is a sectional view taken along line C-C of the essential portion of the integrated thin-film cell shown in FIG. 5. FIG. 8 is a perspective view of an LED lighting device. FIG. 9 is a plan view of an LED substrate constituting the LED lighting device. FIGS. 10 and 11 are diagrams for explaining a production process for the integrated thin-film cell. FIG. 12 is a diagram for explaining a production process for the photovoltaic module. FIG. 13 is an explanatory view illustrating the assembling process for the light source integrated photovoltaic module. FIG. 14 is a front view of a power-generating light-emitting system according to an embodiment. FIG. 15 is a front view of a modification of the power-generating light-emitting system shown in FIG. 14.

Light Source Integrated Photovoltaic Module

As shown in FIGS. 1 to 4, a light source integrated photovoltaic module 60 according to a first embodiment includes a light-transmitting photovoltaic module 10 having the front surface and the back surface and LED lighting devices 50 provided on the back surface side of the photovoltaic module 10. The light source integrated photovoltaic module 60 is configured such that the photovoltaic module 10 generates the electric power by utilizing sunlight 100 incident from the front surface side, the LED lighting device 50 emits an LED light 200 by utilizing the electric power generated by the photovoltaic module 10, and the LED light 200 emitted from the LED lighting device 50 is transmitted through the photovoltaic module 10 and outputted to the front surface side of the photovoltaic module 10.

As shown in FIG. 2, a reflecting plate 40 is provided on the back surface side of the photovoltaic module 10. The reflecting plate 40 accommodates the LED lighting devices 50, and the back surface side of the photovoltaic module 10 is covered with the reflecting plate 40. As shown in FIG. 4, the reflecting plate 40 has a concave shape so as to reflect the LED light 200, emitted from the LED lighting devices 50, to irradiate the back surface of the photovoltaic module 10. The reflecting plate 40 includes a partition plate 41. The partition plate 41 partitions a space defined between the back surface of the photovoltaic module 10 and the reflecting plate 40 in each LED lighting device 50 in order to independently output the LED light 200, emitted from the LED lighting devices 50 arranged in both edges of the photovoltaic module 10, from the front surface side of the photovoltaic module 10. Therefore, the LED light 200 emitted from the LED lighting devices 50 are not mixed together, but independently outputted from the front surface side of the photovoltaic module 10. In this embodiment, the LED light 200 emitted by the left LED lighting device 50 is outputted from the left-half region of the photovoltaic module 10, and the LED light 200 emitted by the right LED lighting device 50 is outputted from the right-half region of the photovoltaic module 10.

As shown in FIG. 1, the photovoltaic module 10 includes two light-transmitting (see-through) integrated thin-film cells 20. As shown in FIGS. 5 to 7, each integrated thin-film cell 20 has a tandem photoelectric conversion layer 26 which is formed by laminating a first photoelectric conversion layer 24 made of amorphous silicon and a second photoelectric conversion layer 25 made of microcrystalline silicon. Slit-shape openings 30 are formed in the photoelectric conversion layer 26. The opening 30 transmits the LED light 200 (see FIG. 4) emitted by the LED lighting device 50 (see FIG. 4) from the back surface side to the front surface side.

In this embodiment, an area ratio of the opening 30 to the effective power generation region of each integrated thin-film cell 20 is about 10%. This means that the transmittance is about 10% in the whole of each integrated thin-film cell 20.

Therefore, as shown in FIG. 1, at the edge where the two integrated thin-film cell 20 come into contact with each other, a black PET film 14 having the transmittance of about 10% is arranged in a transparent trimming portion 32 (see FIG. 5) where the photoelectric conversion layer 26 does not exist such that the transmittance is uniformly maintained in the whole of the photovoltaic module 10.

As shown in FIG. 8, each LED lighting device 50 has the configuration in which four vertically long LED substrates 51 are coupled in a lengthwise direction. As shown in FIG. 9, each LED substrate 51 includes plural LED elements 52 which emit three RGB primary colors and a control circuit (not shown) which controls lighting of each LED element 52 and gradation of the light emission. As described later, the control circuit controls the lighting of each LED element 52 and the gradation of the light emission in each half region of the LED substrate 51. Therefore, in the LED lighting device 50 shown in FIG. 8, the light-emission color can be controlled in each half region of each LED substrate 51. A method of producing the light source integrated photovoltaic module according to the embodiment will be described below.

Process 1: Production of Integrated Thin-film Cell

First, as shown in FIG. 10(a), a glass substrate 21 having a thickness of 1.8 mm is used as an insulating translucent substrate, and an SnO₂ (tin oxide) film is deposited as a transparent conductive film 22 on the glass substrate 21 (substrate size: 560 mm by 925 mm) by thermal CVD method. As shown in FIG. 10(b), patterning of the transparent conductive film 22 is performed using a fundamental wave of YAG laser. The transparent conductive film 22 is separated in a strip shape to form separation lines 23 by causing a laser beam to strike on from the side of the glass substrate 21. Then, ultrasonic cleaning is performed to the obtained glass substrate 21 with pure water.

Then, as shown in FIG. 10(c), a first photoelectric conversion layer 24 is formed with a plasma CVD apparatus. The first photoelectric conversion layer 24 includes an a-Si:H p layer, an a-Si:H i layer, and an a-Si:H n layer, and the first photoelectric conversion layer 24 has the total thickness of about 0.25 μm. As shown in FIG. 10(d), a second photoelectric conversion layer 25 is formed with the plasma CVD apparatus. The second photoelectric conversion layer 25 includes a μc-Si:H p layer, a μc-Si:H i layer, and a μc-Si:H n layer, and the second photoelectric conversion layer 25 has the total thickness of about 1.6 μm. In order to improve characteristics by improving a contact between the first photoelectric conversion layer 24 and the second photoelectric conversion layer 25, a transparent intermediate film may be inserted between the first photoelectric conversion layer 24 and the second photoelectric conversion layer 25. The tandem photoelectric conversion layer 26 is formed of the first photoelectric conversion layer 24 and the second photoelectric conversion layer 25.

Then, as shown in FIG. 10(e), the patterning is performed to the first photoelectric conversion layer 24 and the second photoelectric conversion layer 25 using a second harmonic wave of the YAG laser. The first photoelectric conversion layer 24 and second photoelectric conversion layer 25 are separated in the strip shape to form contact lines 27 by causing the laser beam to strike on from the side of the glass substrate 21. The contact line 27 connects the transparent conductive film 22 and the later-formed back-surface electrode layer 28 (see FIG. 11(f)). Although the second harmonic wave of the YAG laser is used as the laser beam in the embodiment, a third harmonic wave of the YAG laser may be used.

Then, as shown in FIG. 11(f), a ZnO (zinc oxide) layer and an Ag layer are sequentially laminated to form a back-surface electrode layer 28 with a magnetron sputtering apparatus. At this point, the ZnO layer has the thickness of 50 nm and the Ag layer has the thickness of 125 nm. A film such as ITO and SnO₂ having the high translucent property may be used instead of the ZnO layer. The back-surface electrode layer 28 may be configured to neglect the transparent conductive film such as the ZnO layer. However, in order to obtain the high conversion efficiency, it is preferable not to neglect the transparent conductive film.

Then, as shown in FIG. 11(g), the patterning is performed to the back-surface electrode layer 28 with the laser beam. The back-surface electrode layer 28 is separated in the strip shape to form separation lines 29 by causing the laser beam to strike on from the side of the glass substrate 21. At this point, in order to avoid laser-beam damage to the transparent conductive film 22, preferably the second harmonic wave of the YAG laser having good transparency to the transparent conductive film 22 is used as the laser beam to select machining conditions that suppress the damage to the transparent conductive film 22 at the minimum.

Then, as shown in FIG. 11(h), openings 30 are produced by causing the second harmonic wave of the YAG laser to strike on from sectional direction of FIG. 11(h) differs from the sectional direction of FIG. 11(g) by 90°. Therefore, the separation line 29 shown in FIG. 11(g) is not expressed in FIG. 11(h). In the machining conditions in forming the openings 30, as with the formation of the separation line 29 (See FIG. 11(g)) of the back-surface electrode layer 28, it is preferable to select the conditions that do not cause the damage to the transparent conductive film 22. In the opening 30, a width is set at 120 μm and a pitch is set at 1.27 mm. The area ratio of the openings 30 to the effective power generation region is set at about 10% by performing the machining in the above manner. Finally, eight solder-plated bus bars are soldered to a P-side terminal and an N-side terminal to form a collector electrode 31 (see FIG. 5) by pulse heating method. Therefore, the integrated thin-film cell 20 is completed as shown in FIG. 5.

The integrated thin-film cell 20 which is produced in the above manner has the substrate size of 560 mm by 925 mm, 48-step integration, and the opening ratio of 10%. Characteristics of the integrated thin-film cell 20 are measured with a solar simulator AM1.5 (100 mW/cm²). The measurement results are Isc:1.08A, Voc:64.8V, F.F.:0.686, and Pmax:48.0W. In order to prevent the change in color due to oxidation of the Ag layer constituting the back-surface electrode layer 28, the integrated thin-film cell 20 is stored by temporarily sealing the back-surface electrode layer 28 with polyethylene film until the integrated thin-film cells 20 are combined in modules.

Process 2: Production of Photovoltaic Module

In Process 2, the photovoltaic module 10 (see FIG. 1) having three-layer structure sandwiched by glasses is produced using the integrated thin-film cells 20 produced in Process 1. As shown in FIG. 12(a), two EVA sheets 12 as a bonding layer are set on white tempered glass having the substrate size 1120 mm by 983 mm and the thickness of 8 mm which becomes a front surface cover glass 11. The two integrated thin-film cells 20 produced in Process 1 are arranged on the EVA sheets 12. The P-side and N-side collector electrodes 31 (see FIG. 1) of the arranged two integrated thin-film cells 20 which face each other are connected in series with the transparent-PET-coated bus bars 13 (see FIG. 1). The transparent-PET-coated bus bars 13 (see FIG. 1) as a terminal lead line are soldered to the other P-side collector electrode 31 (see FIG. 1) of one cell 20 and the other N-side collector electrode 31 (see FIG. 1) of the other cell 20, which are located at both ends.

Then, as shown in FIG. 12(b), the EVA sheet 12 having the thickness of 0.6 mm is set on the integrated thin-film cells 20 which are arranged and connected in series, and the black PET film 14 is set on the EVA sheet 12 so as to block the transparent trimming portion 32 (see FIG. 5) located at the edge where the integrated thin-film cells 20 are brought into contact with each other. The black PET film 14 has the size of 900 mm by 20 mm and the transmittance of about 10% to the visible light. As shown in FIG. 12(c), the EVA sheet 12 is further laminated on the black PET film 14, and finally the white tempered glass having the substrate size 1120 mm by 983 mm and the thickness of 8 mm is set as a back-surface cover glass 15.

Then, as shown in FIG. 12(d), the module in which the setting is completed in the above manner is integrated to complete the photovoltaic module 10 by melting and bridging EVA while a degree of vacuum and a temperature are adjusted. Then, the unnecessary EVA resin which runs out is removed by end-face processing, terminal boxes 16 (see FIG. 1) are bonded to the glass end face with a silicone resin, and cell terminal lead lines and external cable lines 17 (see FIG. 1) are connected by the soldering in the terminal boxes 16 respectively. Therefore, the photovoltaic module 10 in the state shown in FIG. 1 is obtained. The inside of the terminal box 16 is filled with a potting silicone resin to prevent a short circuit due to water immersion.

The photovoltaic module which is produced in the above manner has the substrate size of 1180 mm by 983 mm, two cells, and the opening ratio of 10%. Characteristics of the photovoltaic module are measured with the solar simulator AM1.5 (100 mW/cm²). The measurement results are Isc:0.972A, Voc: 128V, F.F.:0.686, and Pmax:85.3W.

Process 3: Production of LED Lighting Device

As described above, the LED lighting device 50 shown in FIG. 8 is formed by coupling the four vertically long LED substrates 51 in the lengthwise direction. In FIG. 9, a printed wiring epoxy resin board is used as each LED substrate 51, and a cannon-shot shaped LED element having φ5 is used as the LED element 52. 60 red LED elements, 60 green LED elements, and 60 blue LED elements are mounted on each LED substrate 51, and each LED element 52 is connected to the control circuit (not shown). A control unit of the control circuit is set at 30 red LED elements, 30 green LED elements, and 30 blue LED elements which are arranged in a half region of each LED substrate 51.

As shown in FIG. 8, the four LED substrates 51 are arranged in the lengthwise direction and accommodated in a casing 53 having the size of 930 mm by 65 mm and the thickness of 30 mm. In the casing 53, a front face as a light emission portion is made of transparent polycarbonate, and other portions are made of aluminum, which obtains the good water-proofing property and heat radiation property. As shown in FIG. 2, each LED lighting device 50 having the above configuration is arranged in parallel at the both horizontal edges of the photovoltaic module 10, and the two LED lighting devices 50 are used in light source integrated photovoltaic module 60. Each LED element 52 has eight-level gradation for the red, green, and blue colors, so that 512 colors can be expressed by the combination of the colors. The different colors can independently be expressed in each half region of the LED substrate 51 which is of the control unit. Therefore, eight colors can simultaneously be expressed in one LED lighting device 50 and 16 colors can simultaneously be expressed in light source integrated photovoltaic module 60.

Process 4: Integration of Photovoltaic Module and LED Lighting Device

As shown in FIG. 13, an aluminum module frame 18 is attached to the side face of the photovoltaic module 10 produced in Process 2, the LED lighting device 50 produced in Process 3 is arranged inside the module frame 18, and the reflecting plate 40 having a mirror surface is placed at the back of the photovoltaic module 10. At the central portion, the reflecting plate 40 includes the partition plate 41 which partitions the space into two sections in the lengthwise direction. The LED lighting device 50 is attached after the setting angle is adjusted such that the LED light outputted from the LED lighting device 50 is reflected by the reflecting plate 40 in the back surface and the outputted from the front surface side of the photovoltaic module 10 at the maximum. Thus, the light source integrated photovoltaic module 60 shown in FIGS. 1 and 2 is produced through Processes 1 to 4.

Power-Generating Light-Emitting System

As shown in FIG. 14, in a power-generating light-emitting system 70 according to an embodiment of the present invention, 120 light source integrated photovoltaic modules 60 produced in the above manner are used, eight light source integrated photovoltaic modules 60 are arranged in the lengthwise direction, 15 light source integrated photovoltaic modules 60 are arranged in the crosswise direction, and thereby the large-are self-light emitting type of power-generating light-emitting system having the size of 8 m by 18 m is formed. The 960 LED substrates 51 (see FIG. 9) are used in the whole of the power-generating light-emitting system 70, the control can independently be performed in the 1920 regions, and the 512 colors can be expressed by the combination of the RGB gradations.

The power-generating light-emitting system 70 includes a battery (not shown) and a charge and power supply control unit (not shown). The electric power generated by each light source integrated photovoltaic module 60 during the daytime is stored in the battery. The charge and power supply control unit controls the charge from the light source integrated photovoltaic module 60 to the battery, and the charge and power supply control unit also controls the power supply from the battery to the LED lighting device 50 of the light source integrated photovoltaic module 60. The power-generating light-emitting system 70 can perform the overall plane light emission on the front surface side of the light source integrated photovoltaic module 60 in the nighttime by utilizing the electric power stored during the daytime. Each light source integrated photovoltaic module 60 can simultaneously display 16 colors selected from 512 colors, and the light source integrated photovoltaic module 60 can perform the light-emitting display of the desired characters, graphics, and patterns by appropriately setting and controlling the light source integrated photovoltaic module 60.

As shown in FIG. 15, a logo 71 to be lit up may be arranged in the front surface of the power-generating light-emitting system 70. In this case, the 22 light source integrated photovoltaic modules 60 which are hidden behind the logo 71 are set at the dummy module among the 120 light source integrated photovoltaic modules 60 constituting the power-generating light-emitting system 70. Where the logo 71 is arranged in the front face of the power-generating light-emitting system 70, the power-generating light-emitting system 70 can function as the display device during the daytime in which the power-generating light-emitting system 70 does not emit the light, and the logo 71 is lit up with the LED light in the nighttime. Therefore, the logo 71 can be expressed with high visibility, and the power-generating light-emitting system 70 can be used as the large-size light-emitting advertising display.

### INDUSTRIAL APPLICABILITY

The light source integrated photovoltaic module according to the present invention can be utilized for various displays and lighting applications. For example, the light source integrated photovoltaic module can be utilized for advertising displays of stores and companies, various display panels such as public traffic signals, and lighting devices for family use or business use.

1. A light source integrated photovoltaic module comprising a light-transmitting photovoltaic cell having a front surface and a back surface; and
a light source provided on the back surface side of the photovoltaic cell,
wherein the photovoltaic cell generates electric power by utilizing incident light from the front surface side, the light source emits light by utilizing the electric power generated by the photovoltaic cell, and the light emitted from the light source is transmitted through the photovoltaic cell and outputted to the front surface side of the photovoltaic cell.

2. The light source integrated photovoltaic module as set forth in claim 1, further comprising a reflecting plate covering the back surface side of the photovoltaic cell and accommodating the light source therein,
wherein the photovoltaic cell has a substantially square shape, the light source is arranged along at least one edge of the photovoltaic cell, and the light emitted from the light source is reflected by the reflecting plate and transmitted from the back surface side of the photovoltaic cell to the front surface side.

3. The light source integrated photovoltaic module as set forth in claim 2, wherein the light sources are arranged in both edges of the photovoltaic cell, and the reflecting plate includes a partition plate partitioning a reflection region of each light source so that the light emitted by each light source is independently outputted from the photovoltaic cell.

4. The light source integrated photovoltaic module as set forth in claim 1, wherein the photovoltaic cell has a photoelectric conversion layer for performing photoelectric conversion, and an opening is formed in a part of the photoelectric conversion layer for transmitting the light emitted by the light source from the back surface side to the front surface side.

5. The light source integrated photovoltaic module as set forth in claim 1, wherein the photovoltaic cell has a tandem structure in which a photoelectric conversion layer made of amorphous silicon and a photoelectric conversion layer made of microcrystalline silicon are laminated.

6. The light source integrated photovoltaic module as set forth in claim 1, wherein a reflecting surface is formed on the back surface of the photovoltaic cell for reflecting the light emitted from the light source.

7. The light source integrated photovoltaic module as set forth in claim 4, wherein the opening is formed such that an area ratio of the opening to an effective power generation region of the photovoltaic cell ranges from 5% to 30%.

8. The light source integrated photovoltaic module as set forth in claim 1, wherein the photovoltaic cell comprises a photovoltaic module in which a plurality of integrated cells are arranged so as to adjacent to each other, and a part of the adjacent integrated cells is covered with a film having transmittance similar to transmittance of the whole of the photovoltaic cell.

9. The light source integrated photovoltaic module as set forth in claim 1, wherein the light source comprises an LED lighting device.

10. The light source integrated photovoltaic module as set forth in claim 9, wherein the LED lighting device includes a plurality of LED elements for emitting three RGB primary colors.

11. The light source integrated photovoltaic module as set forth in claim 10, wherein the LED lighting device includes a plurality of LED substrates on which the LED elements are mounted, and each LED substrate includes a control circuit for controlling color development of the LED element.

12. A power-generating light-emitting system comprising a plurality of light source integrated photovoltaic modules arranged in a plane shape or a curved surface shape,
wherein each of the light source integrated photovoltaic modules comprises a light source integrated photovoltaic module as recited in claim 1.

13. The power-generating light-emitting system as set forth in claim 12, further comprising an object to be lit up on the front surface side of a part of the light source integrated photovoltaic modules.
